(19) United States
(12) Patent Application Publication
(10) Pub. No.: US 2008/0037230 A1
(43) Pub. Date: Feb. 14, 2008

(54) Circuit board and chassis

(75) Inventor: Yuki Yoneu, Kitakatsuragi-gun (JP)

Correspondence Address: NIXON & VANDERHYE, PC, 901 NORTH GLEBE ROAD, 11TH FLOOR, ARLINGTON, VA, 22203, US

(73) Assignee: SHARP KABUSHIKI KAISHA, Osaka (JP)

(21) Appl. No.: 11/826,754

(22) Filed: Jul. 18, 2007

(30) Foreign Application Priority Data
Aug. 9, 2006 (JP) 2006-216677

(51) Int. Cl. H01L 23/12; H01R 12/04; H05K 5/00

(52) U.S. Cl. 361/752; 257/723; 438/113; 439/65

(57) ABSTRACT

A circuit board has circuitry including a first part and a second part connected to each other via a given first dividing plane. After the circuitry is divided by the first dividing plane, the circuitry can be restored by reconnecting the first part and the second part. The circuit board further has: first division assisting means for facilitating division of the circuit board; and first connection assisting means for facilitating reconnection of the first part and the second part. This eliminates the need to prepare different circuit boards having different specifications, making it possible to efficiently incorporate the circuit board in as many types of devices as possible.

This nonprovisional application claims priority under 35 U.S.C. § 119(a) on Patent Application No. 2006-216677 filed in Japan on Aug. 9, 2006, the entire contents of which are hereby incorporated by reference.

### BACKGROUND OF THE INVENTION

1. Field of the Invention

The present invention relates to circuit boards having circuits, and to chassis to which a circuit board is secured.

2. Description of Related Art

Conventionally, a circuit board having electronic circuits and a chassis to which the circuit board is secured individually have a fixed shape, and are normally incorporated, as they are, into different types of electronic devices.

As an example of such a conventional circuit board, FIG. 20 shows an outline of the configuration of a circuit board on which circuitry for receiving a digital broadcast wave is formed. Since this circuit board 101 is not assumed to be divided, it is always used in the form of a plate as shown in FIG. 20 while being incorporated in an electronic device or the like.

Incidentally, the digital broadcast wave receiving circuitry 102 formed on the circuit board 101 includes a tuner circuit, a digital demodulation circuit, a video/audio output circuit, and the like. This makes it possible for the circuitry as a whole to receive video or audio data related to a digital broadcast and output the data thus received.

The electronic devices have recently offered, for example, an increased variety of product specifications and higher product performance, resulting in a relatively large circuit area. On the other hand, compact and lightweight electronic devices of diverse shapes are increasingly sought after. The problem here is that, due to limited space, many compact devices cannot incorporate a circuit board having a large circuit area.

To solve this problem, a circuit board may be divided into several pieces, so that these pieces are arranged to fit the shape of a particular device and then connected to each other to restore the circuitry. However, in a case where a circuit board is incorporated in a large device having plenty of space, there is no need to use a circuit board divided into pieces; on the contrary, a step, connecting parts, and the like, for connecting different circuits are wasted.

Alternatively, two types of circuit boards having the same features may be separately prepared. Of these two circuit boards, one (a circuit board divided into pieces, which are later connected to each other) is for a compact device and the other (a normal circuit board, which is not divided into pieces) is for a large device. Depending on the type of device, an appropriate circuit board is used. However, preparing different circuit boards having different specifications brings disadvantages in terms of, for example, design, manufacturing costs, and product management of the circuit board.

### SUMMARY OF THE INVENTION

In view of the conventionally experienced problems described above, it is an object of the present invention to provide circuit boards and chassis that eliminate the need to prepare different circuit boards having different specifications, and that can be efficiently incorporated in as many types of devices as possible.

To achieve the above object, according to one aspect of the present invention, a circuit board is provided with circuitry including a first part and a second part connected to each other via a given first dividing plane. After the circuitry is divided by the first dividing plane, the circuitry can be restored by reconnecting the first part and the second part. The circuit board is further provided with: first division assisting means for facilitating division of the circuit board; and first connection assisting means for facilitating reconnection of the first part and the second part (a first configuration).

With this configuration, it is possible to use a circuit board having a given specification in either of the following two states: the circuit board is divided by the first dividing plane, and the circuit board is used as it is (i.e., without being divided), selecting of which is optional. This eliminates the need to prepare different circuit boards having different specifications, making it possible to efficiently incorporate the circuit board in more types of devices.

That is, when the circuit board is incorporated in a relatively large device, the circuit board is used as it is without being divided. This allows for the omission of a connecting step needed for restoring the divided circuitry. On the other hand, when the circuit board is as it is too large to be incorporated in a device, the circuit board is divided so that it can be incorporated in the device.

Furthermore, since there are provided the first division assisting means for facilitating the division of the circuit board and the first connection assisting means for facilitating the reconnection of the divided circuitry, it is possible to perform efficient division and restoration of the circuit board.

In the first configuration described above, as the first division assisting means, a first indication may be provided for indicating where the first dividing plane lies (a second configuration). With this configuration, when the circuit board is divided by the first dividing plane, it is possible to minimize the possibility of the circuit board being divided at a wrong position.

In the second configuration described above, the first indication may be formed by silk screening or by removing a resist (a third configuration). With this configuration, it is possible to efficiently form the first indication in a step of printing a layer on the circuit board by silk screening or a step of removing a resist, especially when the manufacturing process of the circuit board includes such a step.

In the first configuration described above, as the first division assisting means, a shape may be adopted that causes stress concentration at the first dividing plane when an external force is applied in the direction in which the circuit board is bent at the first dividing plane (a fourth configuration).

With this configuration, by applying an external force to the circuit board in the direction in which the circuit board is bent, it is possible to, for example, break the circuit board at the first dividing plane and easily divide it into separate pieces. In terms of structural mechanics, various shapes such as the V-shaped cut having a pointed end can be adopted as the “shape that causes stress concentration”.

In the fourth configuration described above, the shape may be achieved by forming a V-shaped cut whose pointed end coincides with the first dividing plane (a fifth configuration).

The formation of the V-shaped cut is relatively widely-used processing. In addition, by forming the V-shaped cut from the outside of the circuit board inward so that the pointed end thereof is located inside it, it is possible to cause stress concentration at that pointed end. This makes it possible to efficiently realize the fourth configuration described above.

In the fourth configuration described above, the shape may be achieved by forming perforations at the first dividing plane (a sixth configuration). As is the case with the V-shaped cut, the formation of perforations is relatively widely used processing, and helps cause stress concentration in the perforation forming area. This makes it possible to efficiently realize the fourth configuration described above.

In the circuit board having the first configuration described above, a coating is applied to the circuitry, and the reconnection is achieved by connecting a predetermined conductor to the first part and to the second part. Here, as the first connection assisting means, the coating may be removed from a portion where the conductor is to be connected (a seventh configuration).

With this configuration, since the coating is applied to the circuitry, it is possible to minimize the possibility of foreign materials or the like directly touching the circuitry. On the other hand, since the coating is removed (for example, a hole is formed in the coating layer) from a portion where the conductor (such as a copper wire) is to be connected, it is possible to connect the conductor more smoothly.

In the circuit board having the first configuration described above, the reconnection is achieved by connecting a predetermined conductor to the first part and to the second part. Here, as the first connection assisting means, a land for soldering may be formed in a portion where the conductor is to be connected (an eighth configuration).

With this configuration, it is possible to connect the conductor to the first part and to the second part by soldering the conductor to the land. This makes it possible to efficiently connect the conductor to the first part and to the second part.

The first configuration described above may be configured as follows (a ninth configuration). The circuitry receives a digital broadcast wave related to compressed video or audio data, and outputs the video or audio data. Here, the first part includes a tuner circuit for receiving the digital broadcast wave and converting the digital broadcast wave thus received into a signal having an intermediate frequency, and the second part includes a demodulation circuit for demodulating the signal having an intermediate frequency, and a video/audio output circuit for decompressing and reconstructing the video or audio data and outputting the video or audio data thus reconstructed.

According to another aspect of the present invention, a chassis on which the circuit board having the first configuration described above is immovably placed can be divided with the circuit board being immovably placed thereon by a second dividing plane corresponding to the first dividing plane. Here, the chassis is provided with a second division assisting means for facilitating division of the chassis (a tenth configuration).

With this configuration, it is possible to incorporate the circuit board having the first configuration described above in an electronic device or the like more securely. Moreover, since the chassis can be divided by the second dividing plane, it is possible to deal with a case in which the circuit board is divided for use. In this case, the second division assisting means makes it possible to perform such division efficiently.

In the tenth configuration described above, as the second division assisting means, a second indication may be provided for indicating where the second dividing plane lies (an eleventh configuration). With this configuration, when the chassis is divided by the second dividing plane, it is possible to minimize the possibility of the chassis being divided at a wrong position.

In the eleventh configuration described above, the second indication may be formed by shaving off a portion of the surface of the chassis (a twelfth configuration). With this configuration, it is possible to form the second indication without the need for a printing step.

In the tenth configuration described above, a rib may be provided on a board mounting plane on which the circuit board is mounted or a back face thereof, and, as the second division assisting means, a notch may be formed in the rib so as to intersect the second dividing plane (a thirteenth configuration).

The formation of the rib helps improve the structural strength of the chassis. However, when the chassis is bent at the second dividing plane so that it is broken and divided at the second dividing plane, the rib hinders the chassis from being bent.

This makes it desirable to cut the rib at the second dividing plane. According to this configuration, since the notch is formed, it is easy to cut the rib at the second dividing plane. This helps realize smooth division of the chassis by bending it.

In the tenth configuration described above, a rib may be provided on a board mounting plane on which the circuit board is mounted or a back face thereof. Here, the rib may be formed in such a way that no interference occurs between different parts of the rib when the chassis is bent at the second dividing plane toward a face on which the rib is formed (a fourteenth configuration).

This configuration makes it possible to reinforce the circuit board with the rib, and makes it relatively easy to bend the chassis at the second dividing plane toward a face on which the rib is formed. This makes it easier to break and divide the chassis by bending it at the second dividing plane.

In the tenth configuration described above, the rib may be so shaped that, after the chassis is divided by the second dividing plane into first and second pieces, the first and second pieces thus obtained are fixed to each other by fitting a projection formed in the rib of the first piece into a depression formed in the rib of the second piece (a fifteenth configuration).

With this configuration, after the chassis is divided into the first and second pieces, the projection formed in the rib of one piece is fit into the depression formed in the rib of the other. This makes it easier to fix the positional relationship between them. It should be understood that the term “fix” used here denotes hindering a movement not only in all directions but also in at least a certain direction.

According to still another aspect of the present invention, a method of manufacturing an electronic device is provided with: a step of dividing the circuit board having the first configuration by the first dividing plane; and a step of arranging and fixing pieces produced as a result of division in a given electronic device in such a way that the pieces are laid one on top of another or placed so as to be at nearly right angles to each other. With this method, it is possible to incorporate the circuit board in a relatively small electronic device.

According to still another aspect of the present invention, a method of manufacturing an electronic device is provided with: a step of dividing the chassis having the tenth configuration by the second dividing plane; and a step of arranging and fixing pieces produced as a result of division in a given electronic device in such a way that the pieces are laid one on top of another or placed so as to be at nearly right angles to each other. With this method, it is possible to incorporate the chassis in a relatively small electronic device.

An electronic device provided with the circuit board having the first configuration or the chassis having the tenth configuration offers the advantages of the first or tenth configuration.

### BRIEF DESCRIPTION OF THE DRAWINGS

This and other objects and features of this invention will become clear from the following description, taken in conjunction with the preferred embodiments with reference to the accompanied drawings.

FIG. 1 is a configuration diagram of a circuit board according to a first embodiment of the invention.

FIG. 2 is a sectional view taken on the line A-B of FIG. 1.

FIG. 3 is a diagram showing separate pieces of a circuit board that are placed one on top of another.

FIG. 4 is a diagram showing separate pieces of a circuit board that are placed so as to be at right angles to each other.

FIG. 5 is a diagram showing the circuitry restored after the division of the circuit board.

FIG. 6 is a sectional view taken on the line A-B of FIG. 5.

FIG. 7 is a configuration diagram showing a circuit board according to a second embodiment of the invention.

FIG. 8 is a sectional view taken on the line A-B of FIG. 7.

FIG. 9 is a diagram showing the circuit board having perforations formed therein.

FIG. 10 is a configuration diagram of a circuit board according to a third embodiment of the invention.

FIG. 11 is a sectional view taken on the line A-B of FIG. 10.

FIG. 12 is a configuration diagram of a chassis according to a fourth embodiment of the invention.

FIG. 13 is a diagram showing a circuit board mounted on the chassis shown in FIG. 12.

FIG. 14 is a diagram showing the chassis of FIG. 13, as seen from the side thereof.

FIG. 15 is a diagram showing a notch that is formed instead of the marks shown in FIG. 14.

FIG. 16 is a configuration diagram of a chassis according to a fifth embodiment of the invention.

FIG. 17 is a diagram showing how the chassis is bent.

FIG. 18 is a diagram showing a projection and a depression formed in the rib.

FIG. 19 is a diagram showing how the projection fits into the depression.

FIG. 20 is a configuration diagram of a circuit board for conventional digital broadcast wave receiving circuitry.

### DETAILED DESCRIPTION OF PREFERRED EMBODIMENTS

Hereinafter, first to fifth embodiments of the invention will be described.

### First Embodiment

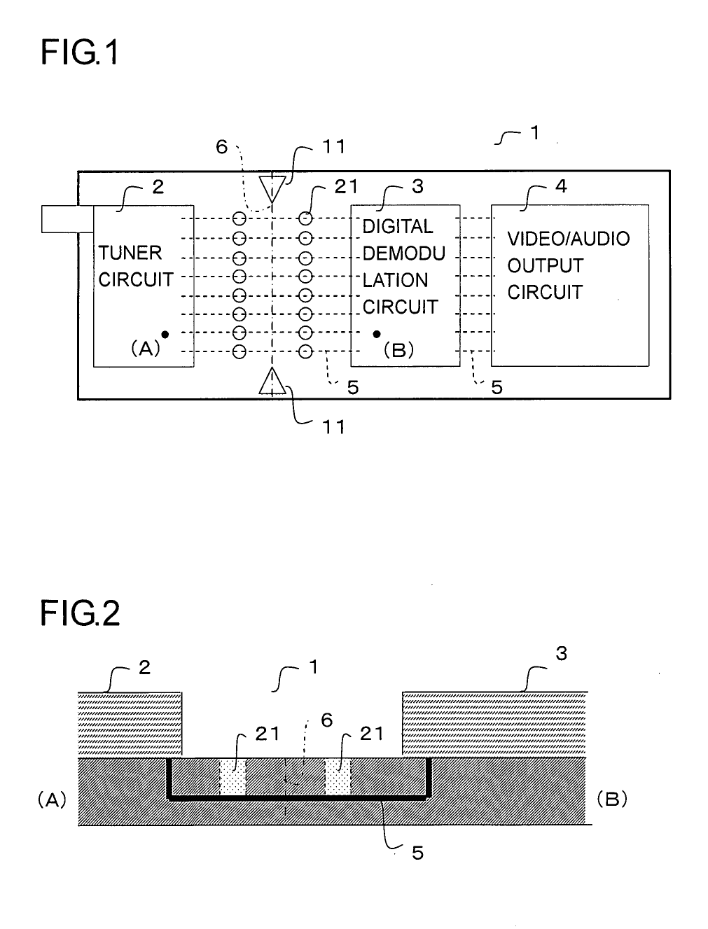

First, a first embodiment will be described, taking up as an example a circuit board on which circuitry for receiving a digital broadcast wave is mounted. FIG. 1 shows an overall configuration diagram of a circuit board according to this embodiment, and FIG. 2 shows a sectional view taken on the line A-B of FIG. 1. As shown in this drawing, the circuit board 1 includes a tuner circuit 2, a digital demodulation circuit 3, a video/audio output circuit 4, a signal line pattern 5, marks 11, insertion holes 21, and the like.

The tuner circuit 2 receives via an antenna a digital broadcast signal related to compressed video or audio data. The tuner circuit 2 also includes an unillustrated frequency selection circuit, so that it receives only a broadcast wave of a desired channel. Additionally, the tuner circuit 2 converts the received signal into a signal having a predetermined intermediate frequency, and then outputs it to a circuit provided in the following stage.

The digital demodulation circuit 3 is connected to the tuner circuit 2 via the signal line pattern 5, and receives the received signal from the tuner circuit 2. The digital demodulation circuit 3 extracts data (compressed video or audio data) related to the received signal, and then outputs it to a circuit provided in the following stage.

The video/audio output circuit 4 is connected to the digital demodulation circuit 3 via the signal line pattern 5, and receives data outputted from the digital demodulation circuit 3. The video/audio output circuit 4 decompresses the data thus received so as to produce video or audio data, and then outputs the resultant data to an unillustrated circuit provided in the following stage.

The signal line pattern 5 is made of a given conductive material. As described above, the signal line pattern 5 connects between the tuner circuit 2, the digital demodulation circuit 3, and the video/audio output circuit 4. On top of the signal line pattern 5, a coating is applied (except for the insertion holes, which will be described later) to prevent foreign materials or the like from directly touching the signal line pattern 5.

It is assumed that there is a board dividing plane 6 between the tuner circuit 2 and the digital demodulation circuit 3. The board dividing plane 6 is an assumed plane formed as a result of the circuit board 1 being physically divided at some future time. Thus, in a part where the board dividing plane 6 lies, the circuit constituent components (different elements such as transistors) other than the signal line pattern 5 are not disposed, so as to allow for easy restoration of the circuitry even after the division thereof. A description will be given below of the dividing method, significance of the division, or the like.

The marks 11 provide an indication of where the board dividing plane 6 lies. In FIG. 1, formed as the marks 11 are isosceles triangles provided on the opposite sides of the board in such a way that they point to each other, indicating the board dividing plane 6 as an imaginary line passing through the vertices thereof. The formation of the marks 11 makes it possible to minimize the possibility of the circuit board 1 being divided at a wrong position.

The marks 11 are formed by silk screening. Thus, the marks 11 can be formed concurrently with a layer printed on the circuit board 1 by silk screening. Alternatively, the marks 11 may be formed by removing a resist in a step of removing the resist during the manufacturing process of the circuit board 1.

The insertion holes 21 are holes formed in the coating on the board (portions where the coating is removed) for inserting connecting wires (such as copper wires). The insertion holes 21 are formed on the signal line pattern 5, making it possible to bring the connecting wires into contact with the signal line pattern 5 via the insertion holes 21. For each trace of the signal line pattern 5, two of the insertion holes 21 are provided, of which one is on the right side of the board dividing plane 6 and the other is on the left side thereof.

With the circuit board 1 configured as described above, it is possible to receive video or audio data related to a digital broadcast, and output the data thus received. To be sure, the circuit board 1 can be used as it is (i.e., without being divided); it is also possible to use the circuit board 1 by dividing it by the board dividing plane 6.

Here, how the circuit board 1 is divided for use (i.e., to be incorporated in a given electronic device) will be described. First, the circuit board 1 is divided into two pieces by the board dividing plane 6. For example, the circuit board 1 is cut by a cutter by referring to the marks 11 and the like, in such a way as not to damage the insertion holes 21.

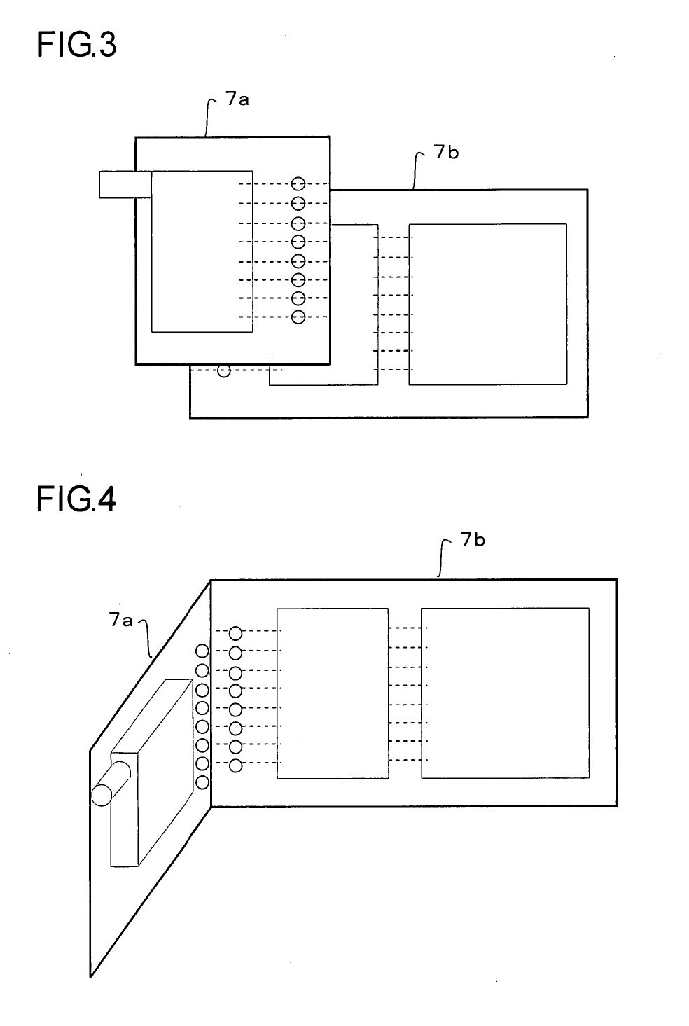

Next, the two pieces of the circuit board 1 thus divided are appropriately arranged inside the device. Although various arrangements are possible, as an example of implementation, FIGS. 3 and 4 respectively show an arrangement in which a piece 7a on which the tuner circuit is provided and a piece 7b on which the digital demodulation circuit is provided are laid (placed) one on top of another, and an arrangement in which the pieces 7a and 7b are placed so as to be at right angles to each other.

By placing the pieces (7a and 7b) one on top of another, it is possible to suitably deal with a case in which, for example, they are incorporated in an electronic device that has overhead clearance, despite having a limited base area. Alternatively, by placing the pieces so as to be at right angles to each other, it is possible to suitably deal with a case in which, for example, they are incorporated in an electronic device which is limited in length along the longer or shorter sides thereof.

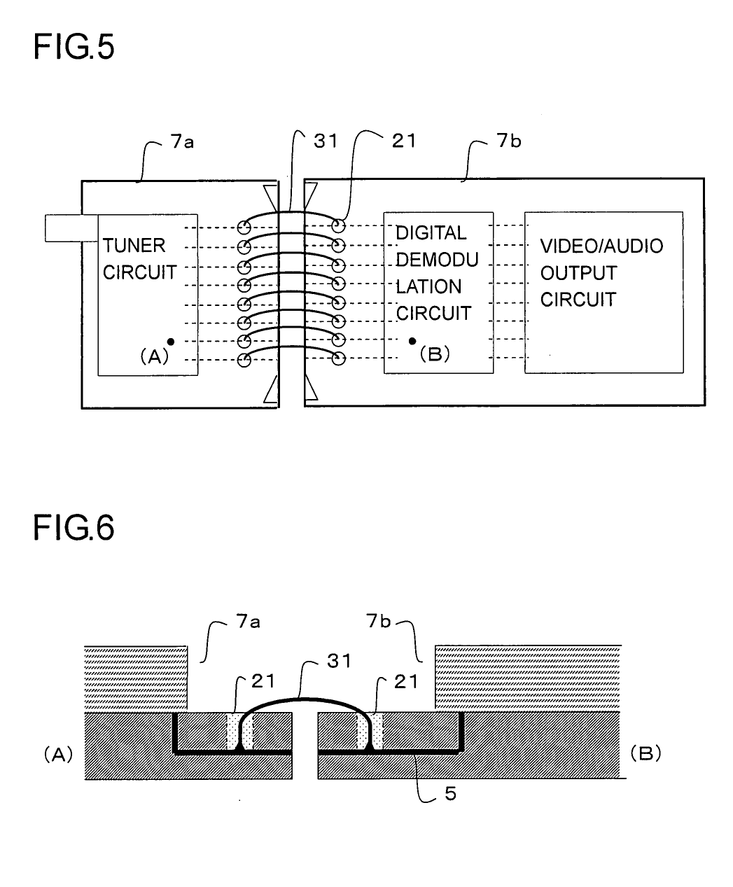

After the pieces are arranged as described above, connecting wires 31 are each inserted into two of the insertion holes 21 formed on the same trace of the signal line pattern 5, and are then connected thereto, whereby the circuit configuration is restored to a pre-divided state. FIG. 5 schematically shows the completion of such connection, and FIG. 6 shows a sectional view taken on the line A-B of FIG. 5. The connecting wires 31 are securely connected to the signal line pattern 5 by soldering or the like.

The descriptions heretofore deal with an example in which the connection of the connecting wires 31 is performed after the pieces (7a and 7b) of the circuit board 1 are arranged in predetermined positions. Alternatively, after the connection of the connecting wires 31 is completed, the pieces (7a and 7b) may be arranged in predetermined positions. In this way, it is possible to manufacture an electronic device incorporating the circuit board of this embodiment.

### Second Embodiment

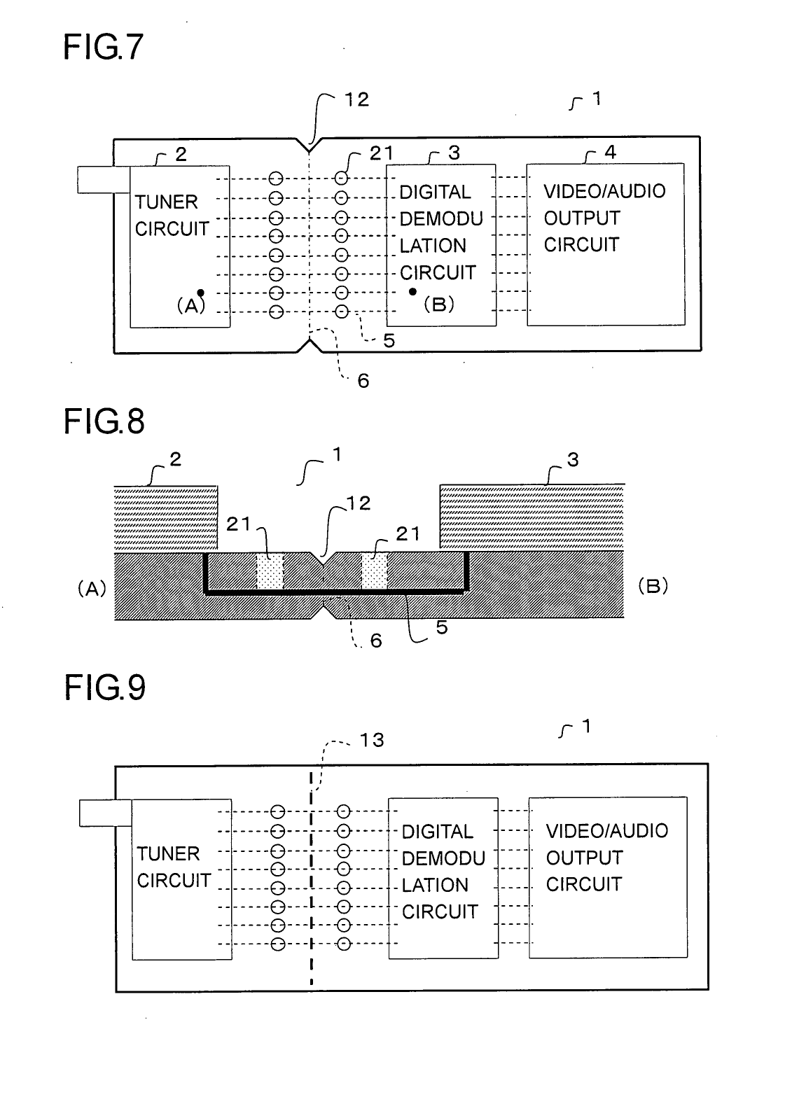

Next, a second embodiment will be described taking up a circuit board as an example, as is the case with the first embodiment. FIG. 7 shows the overall configuration of a circuit board 1, and FIG. 8 shows a sectional view taken on the line A-B of FIG. 7. This embodiment differs from the first embodiment only in the configuration near the board dividing plane 6. In other respects, this embodiment is basically the same as the first embodiment described above, and therefore the explanations of such configurations as are found also in the first embodiment will not be repeated as already given there.

As shown in FIGS. 7 and 8, the circuit board 1 has a V-shaped cut 12 whose pointed end is aligned (coincides) with the board dividing plane 6. This embodiment deals with a case in which the V-shaped cut 12 is formed all around the board dividing plane 6. Alternatively, the V-shaped cut 12 may be formed only in a part thereof (e.g., only in the sides or top and under parts thereof).

The formation of the V-shaped cut 12 makes it easier to divide the circuit board 1 by the board dividing plane 6. That is, since the V-shaped cut 12 makes smaller (minimizes) the cross-sectional area of the circuit board 1 at the board dividing plane 6 than that near the board dividing plane 6, when an external force is applied to the circuit board 1 in the direction in which the circuit board 1 is bent at the board dividing plane 6, stress concentration occurs at the board dividing plane 6. Thus, by applying a given external force strong enough to break the circuit board 1 in the direction in which the circuit board 1 is bent at the board dividing plane 6, it is possible to break the circuit board 1 at the board dividing plane 6 and divide it into separate pieces.

In addition to forming the V-shaped cut 12, or instead of forming the V-shaped cut 12, perforations 13 shown in FIG. 9 may be formed at the board dividing plane 6. Also with this configuration, since the cross-sectional area of the circuit board 1 at the board dividing plane 6 is made smaller than that near the board dividing plane 6, the application of the external force in the direction in which the circuit board 1 is bent results in stress concentration at the board dividing plane 6. This makes it easier to divide the circuit board 1 by the board dividing plane 6.

### Third Embodiment

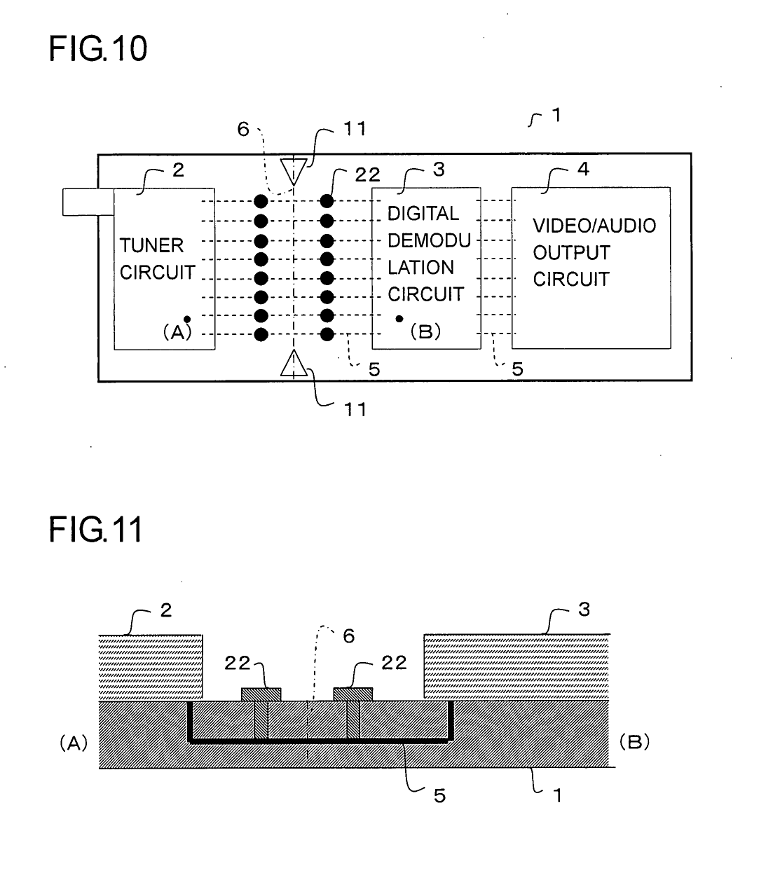

Next, a third embodiment will be described taking up a circuit board as an example, as is the case with the first embodiment. FIG. 10 shows the overall configuration of this circuit board, and FIG. 11 shows a sectional view taken on the line A-B of FIG. 10. This embodiment differs from the first embodiment only in that lands 22 are formed instead of insertion holes 21. In other respects, this embodiment is basically the same as the first embodiment described above, and therefore the explanations of such configurations as are found also in the first embodiment will not be repeated as already given there.

The lands 22 are formed for soldering connecting wires (such as copper wires) thereto. Each of the lands 22 is exposed at one end thereof to the surface of the circuit board 1, and is brought into contact with the signal line pattern 5 at the other end thereof, so that it can connect the connecting wire soldered thereto with the signal line pattern 5. For each trace of the signal line pattern 5, two of the lands 22 are provided, of which one is on the right side of the board dividing plane 6 and the other is on the left side thereof.

In this embodiment, although there is a need to form the lands 22 during the manufacturing process of the circuit board 1, it is possible to connect the connecting wires and the signal line pattern 5 by soldering the connecting wires to the lands 22. Thus, as compared with the first embodiment, it is possible to connect the connecting wires and the signal line pattern 5 more efficiently.

### Fourth Embodiment

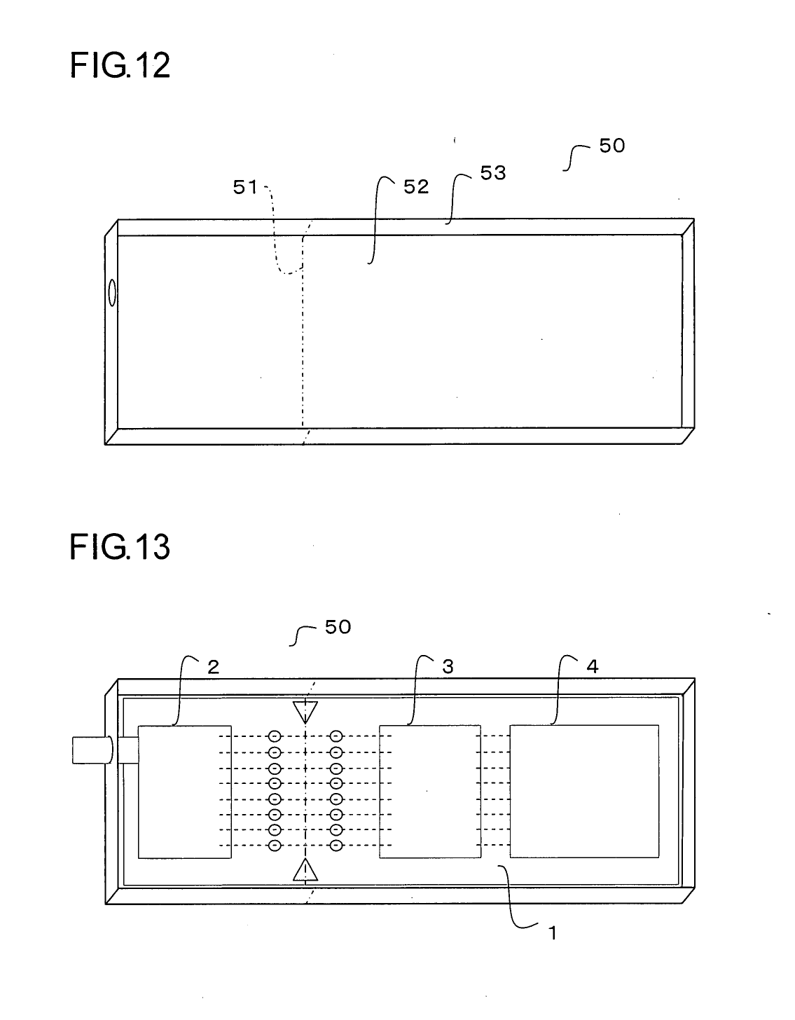

Next, a fourth embodiment will be described, taking up as an example a chassis on which the circuit board described above is immovably placed. FIG. 12 shows an outline of the structure of the chassis, and FIG. 13 shows the circuit board 1 secured to the chassis.

As shown in these drawings, a chassis 50 has, in addition to a board mounting portion 52 on which the circuit board 1 is placed, a rib 53 at the periphery thereof, the rib 53 protruding approximately vertically to the board mounting portion 52. Suppose that the rib 53 is a side face of the chassis 50. Then, the chassis 50 can be regarded as having the shape of a package that can house the circuit board 1. Alternatively, the rib 53 may be provided on the back face (the face on which no circuit board is placed) of the board mounting portion 52.

It is assumed that the chassis 50 has a chassis dividing plane 51 in a portion thereof that corresponds to the board dividing plane 6 of the circuit board 1. The chassis dividing plane 51 is an assumed plane formed as a result of the chassis 50 being physically divided at some future time.

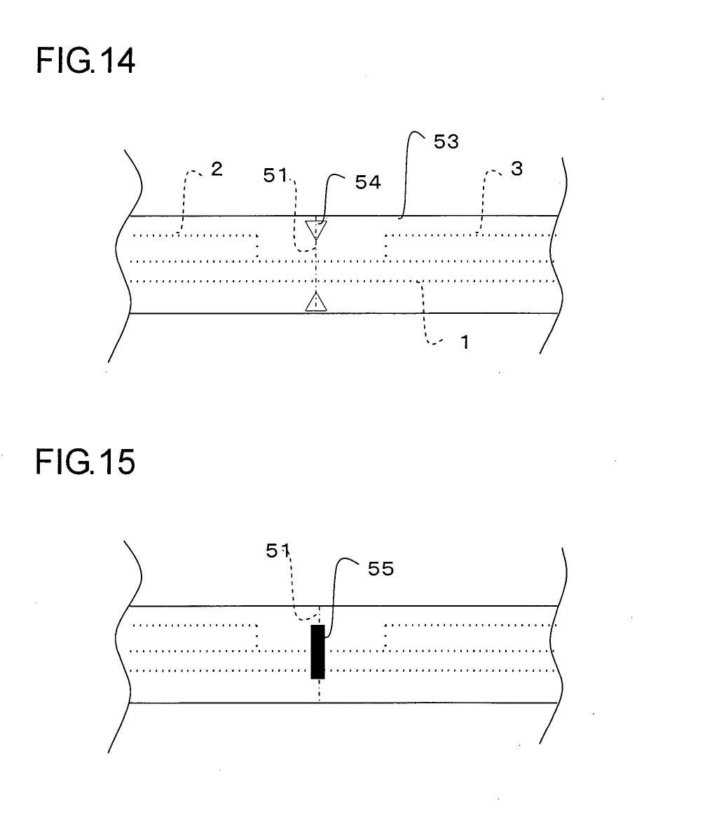

FIG. 14 shows the chassis 50 as seen from a side thereof (as seen from the bottom in FIG. 13). As shown in this drawing, the rib 53 has, on the outer surface thereof, marks 54 indicating where the chassis dividing plane 51 lies. The formation of the marks 54 makes it easy to grasp where the chassis dividing plane 51 lies. Incidentally, the marks 54 are formed by shaving off a portion of the surface of the chassis.

Instead of or in addition to forming the marks 54, a notch 55 shown in FIG. 15 may be formed in the rib 53 so as to interest the chassis dividing plane 51. The formation of the notch 55 allows for easier division of the chassis 50, which will be described later.

With this structure, it is possible to secure the circuit board 1 inside the chassis 50, and incorporate the chassis 50 in a given electronic device or the like. This makes it possible to incorporate the circuit board 1 in the device more easily and safely. To be sure, the chassis 50 can be used as it is (i.e., without being divided); it is also possible to use the chassis 50 by dividing it by the chassis dividing plane 51.

Next, how the chassis 50 is divided for use (i.e., to be incorporated in an electronic device) will be described. First, the circuit board 1 is secured to the chassis 50. At this point, it is preferable to check to make sure the board dividing plane 6 and the chassis dividing plane 51 are fixed in a position where they substantially overlap one another.

Then, based on the marks, if any, formed in the circuit board or the chassis, the chassis 50 is cut by the chassis dividing plane 51 along with the circuit board 1. In this case, advisably, the chassis 50 is cut by a cutter or the like.

As a result of this cutting, the chassis 50 is cut into separate pieces. The resultant pieces are attached to specified positions of the device, and the connecting wires are connected to the circuit board 1. In this way, the circuitry divided as a result of cutting is restored. Incidentally, as is the case with the first embodiment, after the restoration of the circuitry is completed, the chassis may be incorporated in the device.

The separate pieces of the chassis 50 may be attached to the device in various ways. For example, like the arrangements shown in FIGS. 3 and 4, they may be laid (placed) one on top of another, or placed so as to be at right angles to each other. In this way, it is possible to manufacture an electronic device in which the chassis according to this embodiment is incorporated.

Incidentally, the chassis 50 may be cut in such a way that the chassis 50 is broken by the chassis dividing plane 51 by bending it once or repeatedly. In this case, a portion of the rib 53 where the rib 53 intersects the chassis dividing plane 51 is cut by a nipper or the like in advance. This cutting can be easily performed if the notch 55 described above is formed.

Then, an external force is applied to the chassis 50 once or repeatedly in the direction in which the chassis 50 is bent at the chassis dividing plane 51. By doing so, it is possible to divide the chassis into separate pieces. Preferably, to prevent damage resulting from rib-to-rib contact, application of the external force is performed in such a way that the chassis 50 is bent toward a face on which no rib is provided.

The descriptions heretofore deal with a case in which the chassis 50 is divided after the circuit board 1 is secured thereto. Alternatively, for example, the chassis 50 and the circuit board 1 may be individually divided into separate pieces in advance, and then each piece of the circuit board 1 is secured to one of the pieces of the chassis 50.

### Fifth Embodiment

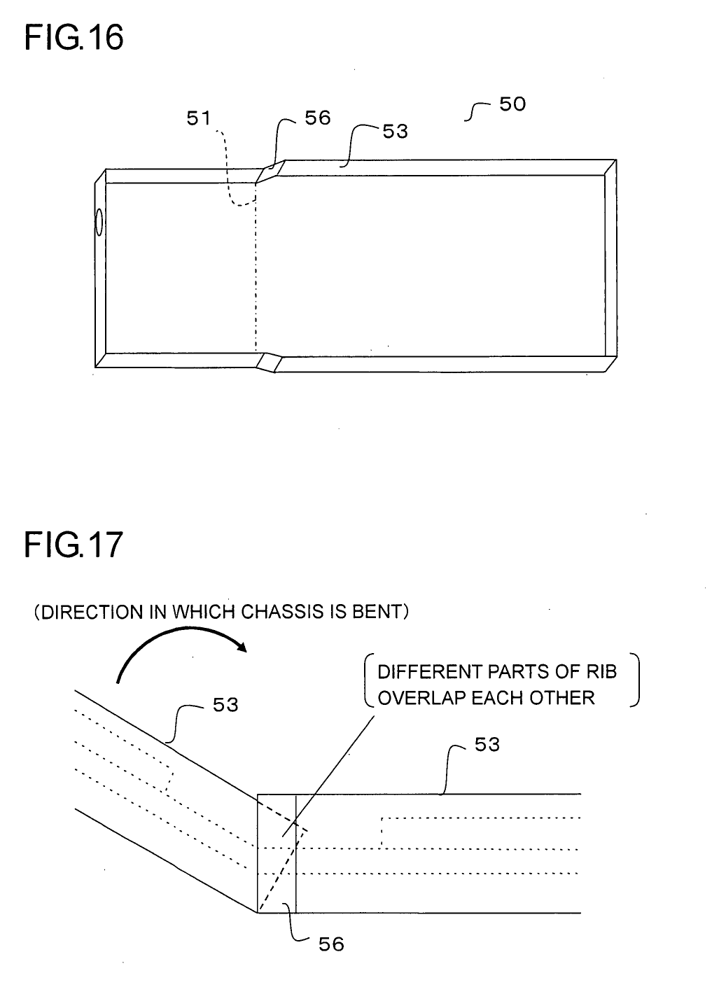

Next, a fifth embodiment will be described, taking up as an example a chassis to which a circuit board is secured, as is the case with the fourth embodiment. FIG. 16 shows an outline of the structure of the chassis. This embodiment differs from the fourth embodiment only in the shape of the rib, for example. In other respects, this embodiment is basically the same as the fourth embodiment described above, and therefore the explanations of such configurations as are found also in the fourth embodiment will not be repeated as already given there.

As shown in this drawing, a rib 53 formed at the outer edge of a chassis 50 has a tapered portion 56 at a chassis dividing plane 51. That is, the chassis 50 shown in FIG. 12 is substantially rectangular in shape (i.e., is substantially uniform in width); in this embodiment, the chassis 50 is so shaped that the chassis dividing plane 51 marks the border between two regions with the tapered portion 56 in between them, of which one has a wider width than the other. The formation of the tapered portion 56 makes it easier to divide the chassis 50.

That is, suppose that there is no tapered portion 56. Then, as shown in FIG. 17, if the chassis 50 is bent toward the face on which the rib 53 is formed, interference occurs between the different parts of the rib 53 located on both sides of the chassis dividing plane 51. By contrast, suppose that the chassis 50 is bent toward the face on which the rib 53 is formed after an incision is made in the tapered portion 56. In this case, as indicated by a broken line in FIG. 17, the tapered portion 56 allows the different parts of the rib 53 to overlap each other, and thereby preventing interference between them.

In other words, the chassis 50 is so shaped that the different parts of the rib 53 do not interfere with each other when the chassis 50 is bent at the chassis dividing plane 51 toward the face on which the rib 53 is formed. This allows the chassis to move in a wider range when it is bent, and hence makes it easier to cut the chassis 50 by bending it. When cutting of the chassis 50 is performed, an incision in a thickness direction is made in advance by a nipper or the like in a portion that corresponds to the tapered portion 56. This process can be omitted if such an incision is made in the tapered portion 56 at the manufacturing stage.

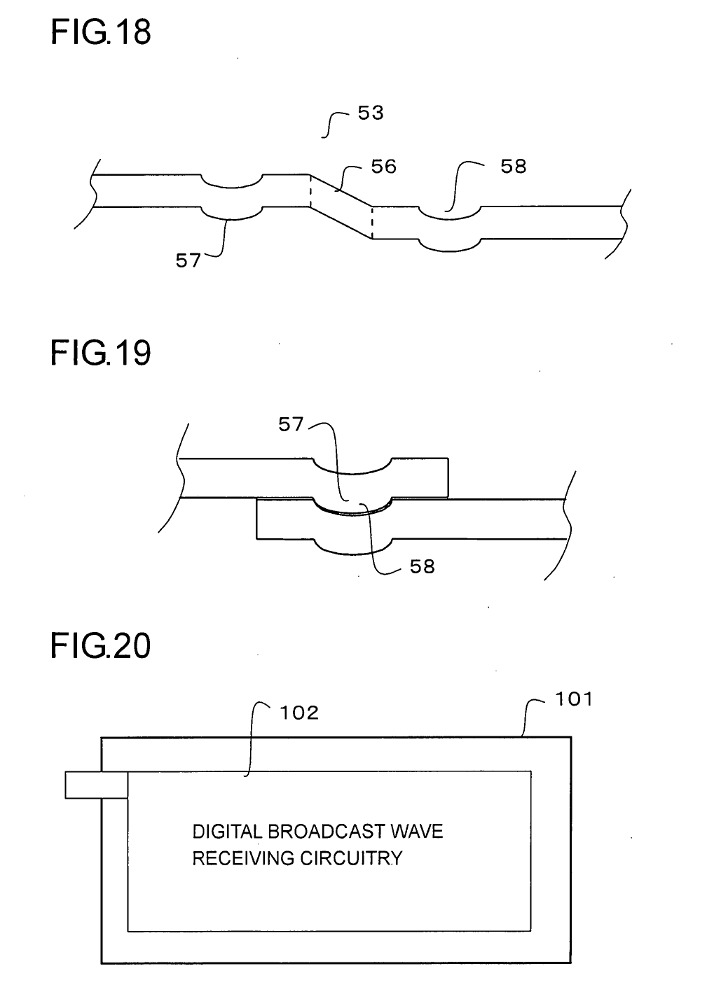

By exploiting the tapered portion 56 thus formed, as shown in FIG. 18, a projection 57 and a depression 58 may be formed for fixing the separate pieces of the chassis to each other. The projection 57 and the depression 58 are formed in pairs (in such a way that the projection fits into the depression) with the chassis dividing plane 51 being interposed between them. Such depression and projection can be formed by, for example, punching the chassis 50 from inside.

As described above, the chassis 50 of this embodiment is divided into two pieces by the chassis dividing plane 51, and the resultant pieces can be fixed to each other by fitting a projection formed in the rib of one piece into a depression formed in the rib of the other.

This makes it easy to fix the separate pieces of the chassis 50 to each other after the division of the chassis 50 without the need for extra parts such as parts for fixing the pieces. That is, as shown in FIG. 19, by fitting the projection 57 into the depression 58, any movement other than the movement in which the projection 57 fits into the depression 58 is restricted.

In addition, by designing the shape of the rib so that appropriate reaction force is generated between the projection 57 and the depression 58, the friction between them helps to some degree restrict the movement in which the projection 57 fits into the depression 58. To fix the pieces to each other more securely, it is necessary simply, for example, to apply an adhesive to the contact areas of each piece.

### Supplementary Note

As described above, the circuit boards 1 described in the first to third embodiments each has digital broadcast wave receiving circuitry including a first part (the tuner circuit 2) and a second part (the digital demodulation circuit 3 and the video/audio output circuit 4) connected to each other by the signal line pattern 5 via the board dividing plane 6. The circuit board 1 is so configured that, even after it is divided by the board dividing plane 6, the circuitry thereof can be restored by reconnecting the first part and the second part with the connecting wires 31.

This makes it possible to use a circuit board having a given specification in either of the following two states: the circuit board is divided by the board dividing plane 6, and the circuit board is used as it is (i.e., without being divided), selecting of which is optional. This eliminates the need to prepare different circuit boards having different specifications, making it possible to efficiently incorporate the circuit board in more types of devices.

That is, when the circuit board is incorporated in a relatively large device, the circuit board 1 is used as it is without being divided. This allows for the omission of a connecting step needed for restoring the divided circuitry. On the other hand, when the circuit board is as it is too large to be incorporated in a device, the circuit board 1 is divided so that it can be incorporated in the device.

By providing means for facilitating the division of the circuit board 1 (first division assisting means; for example, adding the marks 11 or adding the V-shaped cuts 12 or the perforations 13) or means for facilitating the reconnection of the divided circuitry (first connection assisting means; for example, adding the insertion holes 21 or the lands 22), it is possible to perform efficient division and restoration of the circuit board 1.

Incidentally, the chassis described in the fourth or fifth embodiment can be divided by the chassis dividing plane 51 corresponding to the board dividing plane 6 of the circuit board 1 that is secured to the chassis. This makes it possible to divide the chassis to deal with a case in which the circuit board is divided.

By providing means for facilitating the division of the chassis (second division assisting means; for example, adding the marks 54, adding the notch 55, or designing the shape of the chassis so that, when the chassis is bent toward the rib, interference between the different parts of the rib can be prevented), it is possible to perform such division efficiently.

The embodiments described above deal with cases in which the circuit board 1 or the chassis 50 is divided (cut) by the board dividing plane 6 or the chassis dividing plane 51. However, it is also possible simply to bend the circuit board 1 or the chassis 50 (that is, to alter the shape thereof without cutting it). In particular, when the pieces of the circuit board 1 or the chassis 50 need to be arranged in the shape of the letter L, the circuit board 1 or the chassis 50 simply has to be bent by the dividing plane (6 or 51).

In that case, if the signal line pattern 5 is not cut by the dividing plane (6 or 51), there is no need to reconnect the circuitry. However, even when the signal line pattern 5 is cut by the dividing plane (6 or 51), the circuitry can be restored by reconnection using the connecting wires 31.

It is to be understood that the present invention may be practiced in any other manner than specifically described above as the first to fifth embodiments, and various modifications are possible within the scope of the invention. Any feature of the first to fifth embodiments described above can be applied, unless inconsistent, to any embodiment other than that in connection with which the feature is specifically described.

According to the present invention specifically described above as the embodiments, it is possible to use a circuit board having a given specification in either of the following two states: the circuit board is divided by a first dividing plane, and the circuit board is used as it is (i.e., without being divided), selecting of which is optional. This eliminates the need to prepare different circuit boards having different specifications, making it possible to efficiently incorporate the circuit board in more types of devices.

That is, when the circuit board is incorporated in a relatively large device, the circuit board is used as it is without being divided. This allows for the omission of a connecting step needed for restoring the divided circuitry. On the other hand, when the circuit board is as it is too large to be incorporated in a device, the circuit board is divided so that it can be incorporated in the device.

By providing first division assisting means for facilitating the division of the circuit board and first connection assisting means for facilitating the reconnection of the divided circuitry, it is possible to perform efficient division and restoration of the circuit board.

What is claimed is:

1. A circuit board comprising:
circuitry including a first part and a second part connected to each other via a given first dividing plane,
wherein, after the circuitry is divided by the first dividing plane, the circuitry can be restored by reconnecting the first part and the second part,
wherein the circuit board further comprises:
first division assisting means for facilitating division of the circuit board; and
first connection assisting means for facilitating reconnection of the first part and the second part.

2. The circuit board of claim 1, wherein
as the first division assisting means, a first indication is provided for indicating where the first dividing plane lies.

3. The circuit board of claim 2,
wherein the first indication is formed by silk screening or by removing a resist.

4. The circuit board of claim 1,
wherein, as the first division assisting means, a shape is adopted that causes stress concentration at the first dividing plane when an external force is applied in the direction in which the circuit board is bent at the first dividing plane.

5. The circuit board of claim 4, wherein
the shape is achieved by forming a V-shaped cut whose pointed end coincides with the first dividing plane.

6. The circuit board of claim 4, wherein
the shape is achieved by forming perforations at the first dividing plane.

7. The circuit board of claim 1,
wherein a coating is applied to the circuitry, and the reconnection is achieved by connecting a predetermined conductor to the first part and to the second part,
wherein, as the first connection assisting means, the coating is removed from a portion where the conductor is to be connected.

8. The circuit board of claim 1,
wherein the reconnection is achieved by connecting a predetermined conductor to the first part and to the second part,
wherein, as the first connection assisting means, a land for soldering is formed in a portion where the conductor is to be connected.

9. The circuit board of claim 1,
wherein the circuitry receives a digital broadcast wave related to compressed video or audio data, and outputs the video or audio data,
wherein the first part includes a tuner circuit for receiving the digital broadcast wave and converting the digital broadcast wave thus received into a signal having an intermediate frequency,
wherein the second part includes
a demodulation circuit for demodulating the signal having an intermediate frequency, and
a video/audio output circuit for decompressing and reconstructing the video or audio data and outputting the video or audio data thus reconstructed.

10. A chassis on which the circuit board of claim 1 is immovably placed,
wherein the chassis can be divided with the circuit board being immovably placed thereon by a second dividing plane corresponding to the first dividing plane,
wherein the chassis comprises a second division assisting means for facilitating division of the chassis.

11. The chassis of claim 10, wherein
as the second division assisting means, a second indication is provided for indicating where the second dividing plane lies.

12. The chassis of claim 11, wherein
the second indication is formed by shaving off a portion of a surface of the chassis.

13. The chassis of claim 10,
wherein a rib is provided on a board mounting plane on which the circuit board is mounted or a back face thereof,
wherein, as the second division assisting means, a notch is formed in the rib so as to intersect the second dividing plane.

14. The chassis of claim 10,
wherein a rib is provided on a board mounting plane on which the circuit board is mounted or a back face thereof,
wherein the rib is formed in such a way that no interference occurs between different parts of the rib when the chassis is bent at the second dividing plane toward a face on which the rib is formed.

15. The chassis of claim 10, wherein
the rib is so shaped that, after the chassis is divided by the second dividing plane into first and second pieces, the first and second pieces thus obtained are fixed to each other by fitting a projection formed in the rib of the first piece into a depression formed in the rib of the second piece.

16. A method of manufacturing an electronic device, comprising:
a step of dividing the circuit board of claim 1 by the first dividing plane; and
a step of arranging and fixing pieces produced as a result of division in a given electronic device in such a way that the pieces are laid one on top of another or placed so as to be at nearly right angles to each other.

17. A method of manufacturing an electronic device, comprising:
a step of dividing the chassis of claim 10 by the second dividing plane; and
a step of arranging and fixing pieces produced as a result of division in a given electronic device in such a way that the pieces are laid one on top of another or placed so as to be at nearly right angles to each other.

18. An electronic device comprising:
the circuit board of claim 1 or the chassis of claim 10.
